(19) United States
(12) Patent Application Publication
(10) Pub. No.: US 2016/0079537 A1
(43) Pub. Date: Mar. 17, 2016

(54) METHOD OF MANUFACTURING ORGANIC LIGHT-EMITTING DISPLAY APPARATUS

(71) Applicant: SAMSUNG DISPLAY CO., LTD., Yongin-City (KR)

(72) Inventors: Joongu LEE, Yongin-City (KR); Yeonhwa LEE, Yongin-City (KR); Jinbaek CHOI, Yongin-City (KR); Jiyoung CHOUNG, Yongin-City (KR)

(21) Appl. No.: 14/630,679

(22) Filed: Feb. 25, 2015

(30) Foreign Application Priority Data
Sep. 15, 2014 (KR) 10-2014-0122046

(51) Int. Cl. H01L 51/00; H01L 51/56

(52) U.S. Cl. CPC H01L 51/0013; H01L 51/56; H01L 51/5012

(57) ABSTRACT

A method of manufacturing an organic light-emitting display apparatus includes preparing a substrate with a plurality of pixel electrodes, preparing a donor mask, such that the donor mask includes a base substrate, a light-thermal conversion layer on the base substrate, and a reflective layer between the base substrate and the light-thermal conversion layer and having through-holes, depositing a transfer layer on the light-thermal conversion layer of the donor mask, aligning the substrate and the donor mask, preheating at least a portion of the donor mask or the transfer layer, and irradiating a light source toward the preheated portion of the donor mask or the transfer layer, such that a portion of the transfer layer is transferred from the donor mask to the pixel electrodes of the substrate, the transferred portion of the transfer layer corresponding to the through holes in the reflective layer.

### CROSS-REFERENCE TO RELATED APPLICATION

Korean Patent Application No. 10-2014-0122046, filed on Sep. 15, 2014, in the Korean Intellectual Property Office, and entitled: “Method of Manufacturing Organic Light-Emitting Display Apparatus,” is incorporated by reference herein in its entirety.

### BACKGROUND

1. Field

One or more exemplary embodiments relate to a method of manufacturing an organic light-emitting display apparatus, and more particularly, to a method of manufacturing a high-quality organic light-emitting display apparatus.

2. Description of the Related Art

An organic light-emitting display apparatus is a display apparatus having an organic light-emitting device in a display area. The organic light-emitting device mainly includes a pixel electrode, an opposite electrode facing the pixel electrode, and an intermediate layer which is interposed between the pixel electrode and the opposite electrode and includes an emission layer and other layers. At least a portion of the layers included in the intermediate layer are formed to correspond to each sub-pixel.

### SUMMARY

One or more exemplary embodiments include a method of manufacturing a high-quality organic light-emitting display apparatus. However, the embodiments are only illustrative and are not limited thereto.

According to one or more exemplary embodiments, a method of manufacturing an organic light-emitting display apparatus includes preparing a substrate with a plurality of pixel electrodes, preparing a donor mask, such that the donor mask includes a base substrate, a light-thermal conversion layer on the base substrate, and a reflective layer between the base substrate and the light-thermal conversion layer and having through-holes, depositing a transfer layer on the light-thermal conversion layer of the donor mask, aligning the substrate and the donor mask, preheating at least a portion of the donor mask or the transfer layer, and irradiating a light source toward the preheated portion of the donor mask or the transfer layer, such that a portion of the transfer layer is transferred from the donor mask to the pixel electrodes of the substrate, the transferred portion of the transfer layer corresponding to the through holes in the reflective layer.

The transferring may include irradiating a preliminary laser beam on at least a portion of the donor mask to preheat the donor mask or the transfer layer and irradiating the laser beam on the preheated portion of the donor mask or the transfer layer.

The preliminary laser beam may be emitted by a preliminary laser beam source, and the laser beam may be emitted by a laser beam source.

The preliminary laser beam and the laser beam may be emitted by one laser beam source.

The preliminary laser beam and the laser beam may be diverged from an original laser beam emitted by the one laser beam source.

The one laser beam source may emit the preliminary laser beam and the laser beam with a time difference therebetween.

The intensity of the preliminary laser beam may be weaker than the intensity of the laser beam.

The transferring may include irradiating a preliminary lamp light on at least a portion of the donor mask to preheat the donor mask or the transfer layer and irradiating the lamp light on the preheated portion of the donor mask or the transfer layer.

The preliminary lamp light may be emitted by a preliminary lamp, and the lamp light may be emitted by a lamp.

The preliminary lamp light and the lamp light may be emitted by one lamp.

The one lamp may emit the preliminary lamp light and the lamp light with a time difference therebetween.

The intensity of the preliminary lamp light may be weaker than the intensity of the lamp light.

### BRIEF DESCRIPTION OF THE DRAWINGS

Features will become apparent to those of ordinary skill in the art by describing in detail exemplary embodiments with reference to the attached drawings, in which:

FIGS. 1 to 4 illustrate cross-sectional diagrams of stages in a method of manufacturing an organic light-emitting display apparatus according to an exemplary embodiment according to an exemplary embodiment;

FIG. 5 illustrates a side view of a manufacturing process in a method of manufacturing an organic light-emitting display apparatus according to an exemplary embodiment; and

FIG. 6 illustrates a side view of a manufacturing process in a method of manufacturing an organic light-emitting display apparatus according to another exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

As used herein, the term “and/or” includes any and all combinations of one or more of the associated listed items. Further, in the following examples, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

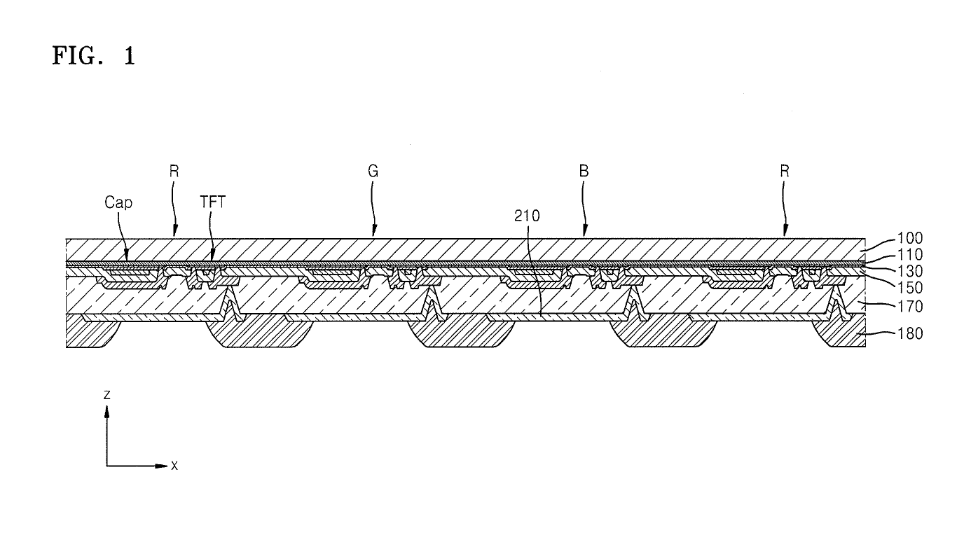

Referring to FIG. 1, a backplane is prepared. The backplane may be a substrate 100 on which a plurality of pixel electrodes 210 are formed. As shown in FIG. 1, the backplane may also include a pixel defining layer 180 formed so as to expose at least a portion of a central part of each of the pixel electrodes 210. The pixel defining layer 180 may protrude from the substrate 100 when compared with the pixel electrodes 210.

The pixel electrode 210 may be a transparent (or translucent) electrode or a reflective electrode. If the pixel electrode 210 is a transparent (or translucent) electrode, the pixel electrode 210 may be formed of, e.g., indium tin oxide (ITO), indium zinc oxide (IZO), zinc oxide (ZnO), indium oxide (In₂O₃), indium gallium oxide (IGO), or aluminum zinc oxide (AZO). If the pixel electrode 210 is a reflective electrode, the pixel electrode 210 may include a reflective layer formed of, e.g., silver (Ag), magnesium (Mg), aluminum (Al), platinum (Pt), palladium (Pd), gold (Au), nickel (Ni), neodymium (Nd), iridium (Ir), chromium (Cr), a compound thereof, or the like, and a layer formed of, e.g., ITO, IZO, ZnO, or In₂O₃. However, the configuration and materials of the pixel electrode 210 are not limited thereto, and various modifications may be performed.

The pixel defining layer 180 may define pixels with openings corresponding to respective sub-pixels, i.e., openings for exposing the central parts of the pixel electrodes 210 or entire surfaces of the pixel electrodes 210. In addition, the pixel defining layer 180 may prevent the occurrence of an electric arc and the like at an end portion of the pixel electrode 210 by increasing a distance between the end portion of the pixel electrode 210 and an opposite electrode (not shown) on an upper part of the pixel electrode 210.

The backplane may further include other various components according to circumstances. For example, as shown in FIG. 1, a thin-film transistor TFT and a capacitor Cap may be formed on the substrate 100. In addition, the backplane may include a buffer layer 110 formed on the substrate 100 to prevent permeation of impurities into a semiconductor layer of the thin-film transistor TFT. Further, the backplane may include a gate insulating layer 130 for insulating the semiconductor layer and a gate electrode of the thin-film transistor TFT, an interlayer insulating layer 150 for insulating source and drain electrodes and the gate electrode of the thin-film transistor TFT, a planarization layer 170, which covers the thin-film transistor TFT and of which an upper surface is almost flat, and other components.

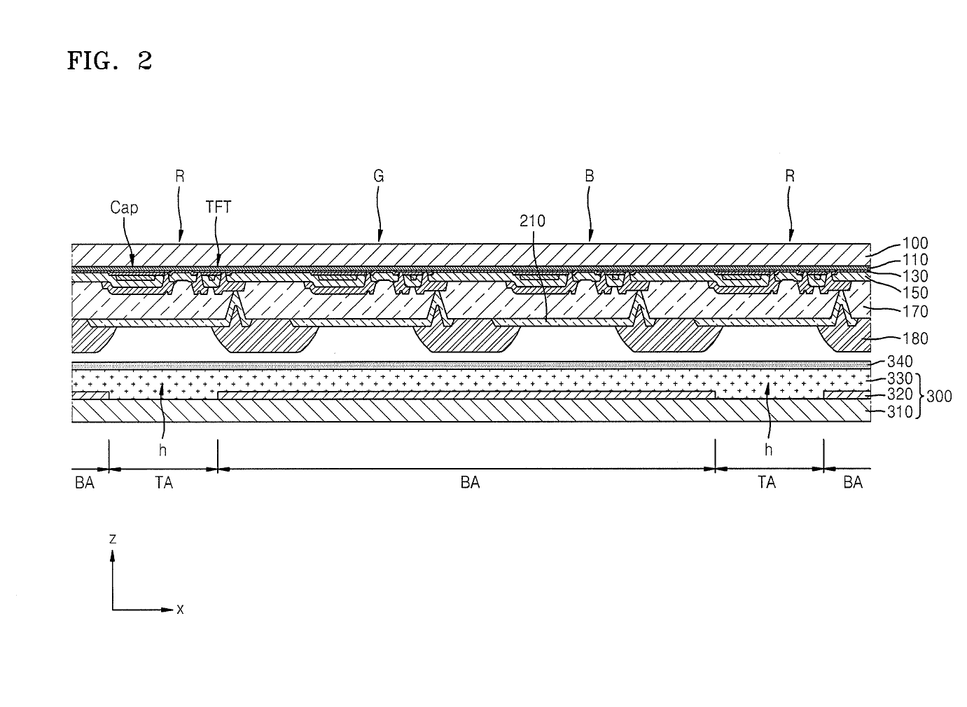

Next, referring to FIG. 2, after preparing the backplane, a donor mask 300 is prepared and disposed so as to face the pixel electrodes 210 and the pixel defining layer 180 of the backplane. In detail, as shown in FIG. 2, the pixel electrodes 210 and the pixel defining layer 180 of the backplane are oriented in a lower direction (−z direction), and the donor mask 300 is disposed below the backplane. Before the backplane and the donor mask 300 are arranged, layers, e.g., a hole injection layer, a hole transport layer, and the like, may be formed in advance on the pixel electrodes 210 or on the entire surface of the substrate 100. Although FIG. 2 illustrates that a considerable space exists between the donor mask 300 and the backplane, this is only for convenience of description, and the donor mask 300 and the backplane may be closely attached to each other.

As further illustrated in FIG. 2, the donor mask 300 may include a base substrate 310, a reflective layer 320, and a light-thermal conversion layer 330. After preparing the donor mask 300, a transfer layer 340 is formed on the light-thermal conversion layer 330 by deposition. According to embodiments, the transfer layer 340 may be considered as one component of the donor mask 300. In this case, the donor mask 300 includes the base substrate 310, the reflective layer 320, the light-thermal conversion layer 330, and the transfer layer 340.

The base substrate 310 forms the general outer appearance of the donor mask 300, and may be formed of a transparent material, e.g., glass, to allow light to reach the light-thermal conversion layer 330. In another example, the base substrate 310 may be formed of a polyester, e.g., polyethylene terephthalate (PET), polyacryl, polyepoxy, polyethylene and/or polystyrene.

The light-thermal conversion layer 330 absorbs a flash lamp light or a laser beam irradiated thereon and converts at least a portion of the absorbed energy of the flash lamp light or the laser beam into heat. The light-thermal conversion layer 330 may be a layer made of metal, e.g., Al or Ag, an oxide/sulfide layer of the metal, or a high-molecular organic layer including, e.g., carbon black, graphite, or the like, which are capable of absorbing light of an infrared-visible light band.

The reflective layer 320 is interposed between the base substrate 310 and the light-thermal conversion layer 330. The reflective layer 320 includes a plurality of through holes h, so the base substrate 310 and the light-thermal conversion layer 330 may contact each other through the through holes h of the reflective layer 320. Accordingly, the reflective layer 320 has transmission areas TA corresponding to the through holes h and a block area BA corresponding to the other portion. That is, the through holes h in the reflective layer 320 define the transmission areas TA that transmit light therethrough, e.g., transmit visible light through the reflective area 320 and an entire thickness of the mask 300, while areas of the reflective area 320 other than the through holes h, i.e., areas of the reflective layer 320 including reflective material, define the block areas BA that block light transmittance therethrough.

The reflective layer 320 may be formed by forming the plurality of through holes h by using a mask on the base substrate 310. For example, forming the reflective layer 320 may include forming a layer having a uniform thickness, followed by removing a portion of the formed layer via use of the mask to define the plurality of through holes h in the formed layer. For example, the reflective layer 320 may be formed of, e.g., titanium (Ti), Al, copper (Cu), Ag, molybdenum (Mo), an alloy thereof, chromium nitride (CrN), TiAlCu, or the like. In another example, the reflective layer 320 may be formed of, e.g., titanium oxide (TiOₓ), silicon oxide (SiOₓ), silicon carbon nitride (SiCN), or the like.

The transfer layer 340 is a layer which may be evaporated, vaporized, or sublimed by the heat generated by the light-thermal conversion layer 330. That is, a portion of the transfer layer 340 that absorbs the heat generated by the light-thermal conversion layer 330 is transferred to the backplane. For example, the transfer layer 340 may be a layer including, e.g., an emission material. In another example, the transfer layer 340 may also be a layer including a hole injection material, a layer including a hole transport material, a layer including an electron transport material, or a layer including an electron injection material.

According to embodiments, the donor mask 300 may further include an insulating layer (not shown) interposed between the reflective layer 320 and the light-thermal conversion layer 330, e.g., the insulating layer may include openings corresponding to the through holes h of the reflective layer 320. The insulating layer may prevent or reduce the delivery of heat generated by the light-thermal conversion layer 330 to the reflective layer 320. If heat generated in the light-thermal conversion layer 330 is transferred to the reflective layer 320, it may then be delivered to the block area BA along the reflective layer 320, rather than to the transmission areas TA, thereby evaporating, vaporizing, or subliming a portion of the transfer layer 340 in the block area BA (which would cause incorrect formation of an emission layer on the backplane).

As shown in FIG. 2, the backplane and the donor mask 300 are aligned, so that the transmission areas TA of the reflective layer 320 of the donor mask 300 correspond to preset portions of the backplane. That is, the through holes h of the reflective layer 320 of the donor mask 300 correspond to, e.g. overlap, respective pixel electrodes 210. For example, the backplane and the donor mask 300 may be aligned, such that the through holes h of the reflective layer 320 and the respective pixel electrodes 210 completely overlap each other, e.g., a width of the through holes h in the x direction may equal and completely overlap a width of the corresponding exposed portions of the pixel electrode 210. For example, as illustrated in FIG. 2, when the transfer layer 340 on the donor mask 300 includes an emission material capable of emitting a red light, the backplane and the donor mask 300 are aligned so that the through holes h of the reflective layer 320 of the donor mask 300 correspond to pixel electrodes 210 of red sub-pixels R.

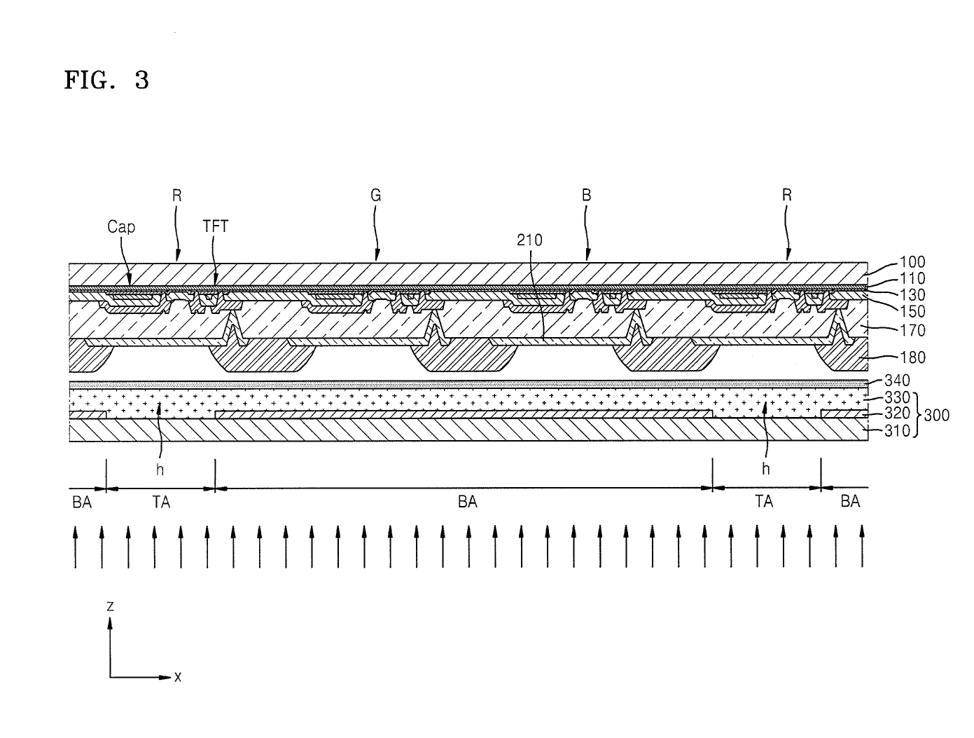

Thereafter, as shown in FIG. 3, a lamp light or a laser beam is irradiated on, e.g., toward, the donor mask 300 by using a flash lamp (not shown) or a laser beam oscillator (not shown). The lamp light or a laser beam is positioned below the mask 300, i.e., such that the mask 300 is between the light and the backplane, and the light is irradiated through the mask 300 toward the backplane.

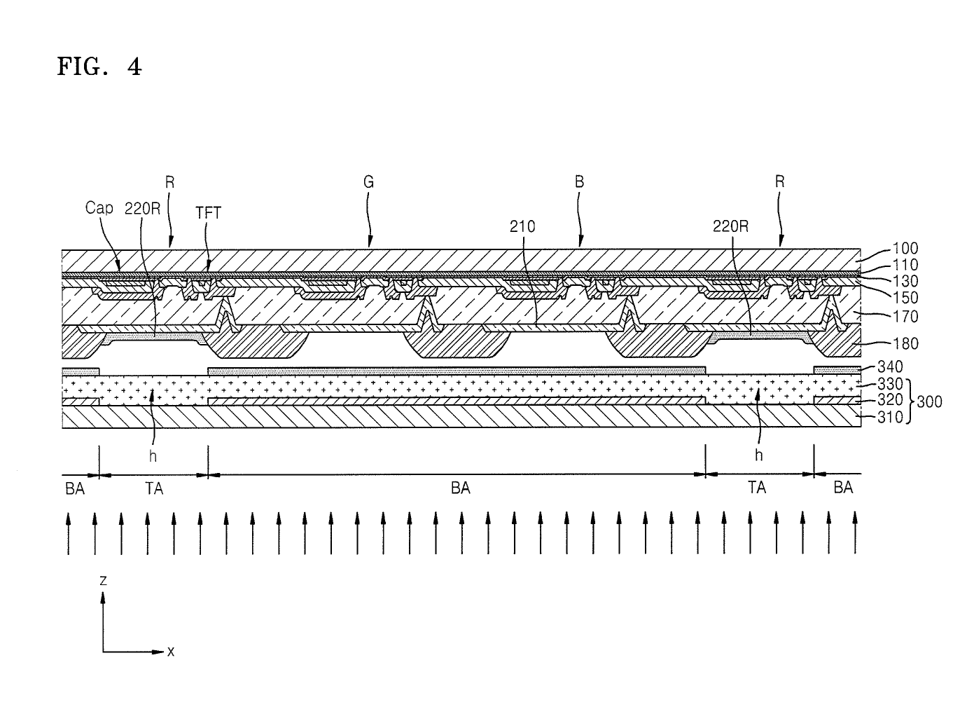

As illustrated in FIG. 4, as a result of the light irradiation, a portion of the transfer layer 340 is transferred from the donor mask 300 to the backplane, i.e., to the exposed pixel electrode 210. In this case, even though the lamp light or the laser beam is irradiated onto the entire surface of the donor mask 300 by using the flash lamp or the laser beam oscillator, most of the lamp light or the laser beam is blocked by the reflective layer 320, and only a portion of the lamp light or the laser beam reaches the light-thermal conversion layer 330 through the transmission areas TA corresponding to the through holes h of the reflective layer 320. Accordingly, only a portion of the transfer layer 340 on the donor mask 300, which corresponds to the transmission areas TA, is transferred to the backplane, i.e., evaporated, vaporized, or sublimed. As such, only the portion of the transfer layer 340 irradiated with the light and transferred to the pixel electrode 210 forms an emission layer, e.g., a red emission layer 220R, on the pixel electrode 210, e.g., of red sub-pixels R. Further, as the through holes h are accurately aligned with the pixel electrodes 210, the portion of the transfer layer 340 irradiated with the light is transformed only to the pixel electrode 210.

As discussed previously, even though the donor mask 300 is illustrated as spaced apart from the backplane, this is only for convenience of description, and the donor mask 300 and the backplane may be closely attached to each other. The close attachment between the donor mask 300 and the backplane increases transfer accuracy of a portion of the transfer layer 340 to the backplane. When a distance between the donor mask 300 and the backplane is large, even though only a portion of the transfer layer 340 on the donor mask 300, which corresponds to the transmission areas TA, is evaporated, vaporized, or sublimed, the evaporated, vaporized, or sublimed material may move not only onto the pixel electrodes 210 of corresponding sub-pixels but also onto pixel electrodes 210 of neighboring sub-pixels.

After forming the red emission layers 220R as described above, green emission layers or blue emission layers may be formed on the pixel electrode 210 of green sub-pixels G or blue sub-pixels B by exchanging the donor mask 300. In addition, according to embodiments, an organic light-emitting display apparatus may be manufactured by forming an electron injection layer, an electron transport layer, and the like, followed by forming opposite electrodes corresponding to the red sub-pixels R, the green sub-pixels G, and the blue sub-pixels B.

In the method of manufacturing an organic light-emitting display apparatus, when the portion of the transfer layer 340 on the donor mask 300, which corresponds to the transmission areas TA, is evaporated, vaporized, or sublimed, and then transferred to the pixel electrodes 210 on the backplane, a layer of a preset thickness is accurately formed to have uniform quality on the pixel electrodes 210. That is, the transfer layer 340 on the donor mask 300 may have a uniform thickness, so a thickness of the transferred portion (to be formed on the pixel electrode 210) is uniform.

To this end, before the portion of the transfer layer 340 on the donor mask 300, which corresponds to the transmission areas TA, is evaporated, vaporized, or sublimed, at least a portion of the donor mask 300 or the transfer layer 340 is preheated. That is, the layer having the preset thickness is accurately formed on the pixel electrodes 210 with uniform quality by preheating at least a portion of the donor mask 300 or the transfer layer 340, before transforming a portion of the transfer layer 340 by irradiating a laser beam or a lamp light on the preheated portion of the donor mask 300 or the transfer layer 340. The reason for this is that the transfer layer 340 corresponding to the preheated portion is accurately evaporated, vaporized, or sublimed when the laser beam or the lamp light is irradiated in a state where the donor mask 300 or the transfer layer 340 is preheated. If the laser beam or the lamp light is irradiated in a state where the donor mask 300 or the transfer layer 340 is not preheated, not all of the portion of the transfer layer 340, which corresponds to the transmission areas TA, is evaporated, vaporized, or sublimed, and a portion thereof remains on the donor mask 300, thereby resulting in an abnormality of the layer of the preset thickness.

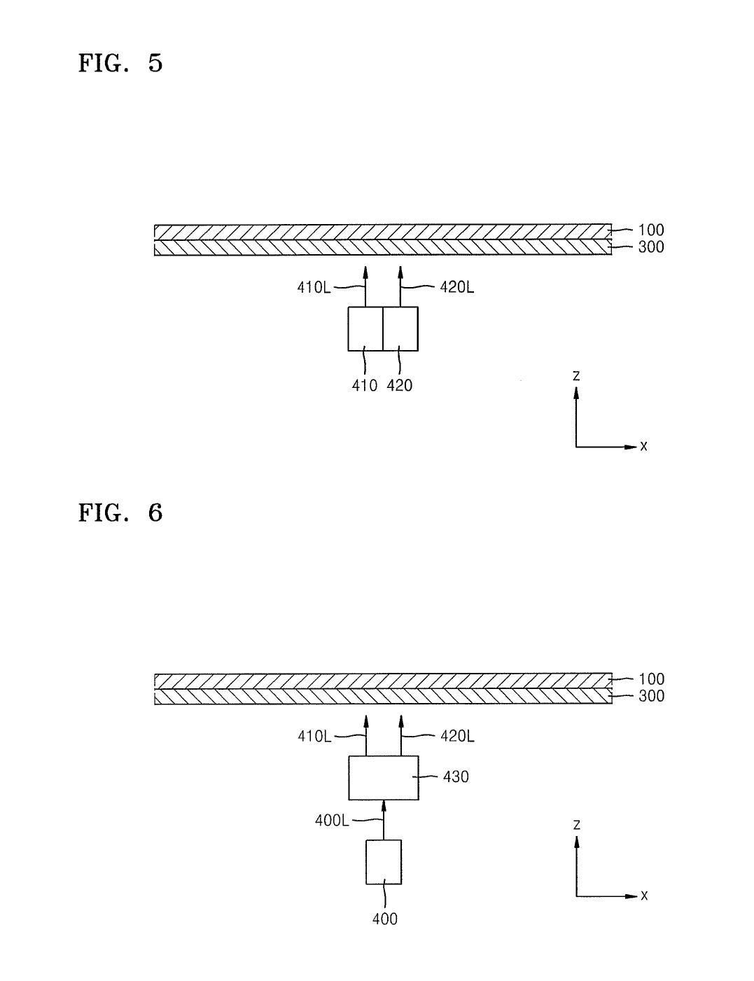

The preheating of at least a portion of the donor mask 300 or the transfer layer 340 may be performed by various methods. For example, as shown in FIG. 5 which is a side view for describing a manufacturing process in the method of manufacturing the organic light-emitting display apparatus according to an exemplary embodiment, at least a portion of the donor mask 300 may be preheated by irradiating a preliminary laser beam 410L thereon. Once a portion of the donor mask 300 is preheated, a laser beam 420L may be irradiated on the preheated portion of the donor mask 300 to transfer a corresponding portion of the transfer layer 340. In this case, as shown in FIG. 5, the preliminary laser beam 410L may be emitted by a preliminary laser beam source 410, and the laser beam 420L may be irradiated by a laser beam source 420. For convenience, FIG. 5 illustrates only the substrate 100.

The preliminary laser beam 410L and the laser beam 420L may have a size corresponding to the substrate 100 of the backplane or may have a size that is less than that of the substrate 100 of the backplane. For example, in FIG. 5, each of the preliminary laser beam 410L and the laser beam 420L may have a long shape having a long axis corresponding to a y axis (an axis directed into the page). In this case, when the substrate 100 and the donor mask 300 move in a (+x) direction, while the preliminary laser beam 410L and the laser beam 420L are irradiated, the laser beam 420L may be naturally irradiated, e.g., immediately, onto a portion of the donor mask 300 on which the preliminary laser beam 410L has already been irradiated. In other words, the preliminary laser beam 410L and the laser beam 420L may be sequentially irradiated onto a same predetermined area of the donor mask 300, with the laser beam source 420 irradiating an area previously irradiated, i.e., preheated, by the preliminary laser beam source 410.

In another example, the preliminary laser beam source 410 and the laser beam source 420 move in a (−x) direction, while the substrate 100 and the donor mask 300 are fixed. In this case, the laser beam 420L may be naturally irradiated on a portion of the donor mask 300 on which the preliminary laser beam 410L has already been irradiated, since the preliminary laser beam source 410 is located at a portion of the (−x) direction relative to the laser beam source 420. In other words, the preliminary laser beam 410L and the laser beam 420L may be sequentially irradiated onto a same predetermined area of the donor mask 300, with the laser beam source 420 irradiating an area previously irradiated, i.e., preheated, by the preliminary laser beam source 410.

In yet another example, as shown in FIG. 6 which is a side view for describing a manufacturing process in the method of manufacturing the organic light-emitting display apparatus according to another exemplary embodiment, the preliminary laser beam 410L and the laser beam 420L may be emitted by a single laser beam source 400. In this case, the preliminary laser beam 410L and the laser beam 420L may be diverged by an optical element 430, e.g., including a beam splitter, a reflective mirror, and the like, from an original laser beam 400L emitted by the laser beam source 400. It is noted that only the laser beam source 400 without the optical element 430 may be used. That is, the laser beam source 400 may first emit the preliminary laser beam 410L, and subsequently, emit the laser beam 420L after a predetermined time period.

When the donor mask 300 or the transfer layer 340 is preheated through the preliminary laser beam 410L by the various methods described above, and thereafter a preset portion of the transfer layer 340 is evaporated, vaporized, or sublimed by irradiating the laser beam 420L to deposit a layer of a preset thickness on the pixel electrodes 210 of the backplane, the intensity of the preliminary laser beam 410L may be weaker than the intensity of the laser beam 420L in order not to evaporate, vaporize, or sublime the transfer layer 340 when the preliminary laser beam 410L is irradiated and to evaporate, vaporize, or sublime the transfer layer 340 when the laser beam 420L is irradiated. In other words, the intensity of the preliminary laser beam 410L is weaker than the that of the laser beam 420L to ensure that the preliminary laser beam 410L only preheats a predetermined area (rather than transforming it), while the intensity of the laser beam 420L is sufficiently high to transfer a portion of the transfer layer 340.

Although it has been described that a layer is deposited on the pixel electrodes 210 of the backplane by irradiating a laser beam to evaporate, vaporize, or sublime the transfer layer 340 on the donor mask 300, the exemplary embodiments described above are not limited thereto. For example, at least a portion of the donor mask 300 may be preheated by irradiating a preliminary lamp light (rather than a laser) thereon, and a lamp light may also be irradiated to the preheated portion to facilitate transfer thereof.

In this case, similarly to the embodiment illustrated in FIG. 5, the preliminary lamp light may be emitted by a preliminary lamp, and the lamp light may be emitted by a separate lamp that is different from the preliminary lamp. Alternatively, similarly to the embodiment illustrated in FIG. 6, the preliminary lamp light and the lamp light may be emitted by one lamp, and in this case, the one lamp may emit the preliminary lamp light and then emit the lamp light with a time difference therebetween.

When the donor mask 300 or the transfer layer 340 is preheated through the preliminary lamp light by the various methods described above, and thereafter a preset portion of the transfer layer 340 is evaporated, vaporized, or sublimed by irradiating the lamp light to deposit a layer of a preset thickness on the pixel electrodes 210 of the backplane, the intensity of the preliminary lamp light may be weaker than the intensity of the lamp light. This is not to evaporate, vaporize, or sublime the transfer layer 340 when the preliminary lamp light is irradiated and to evaporate, vaporize, or sublime the transfer layer 340 when the lamp light is irradiated. That is, the intensity of the preliminary lamp light is weaker than the intensity of the lamp light capable of evaporating, vaporizing, or subliming the transfer layer 340.

By way of summation and review, in an organic light emitting diode of an organic light emitting diode display, a portion of each of the layers included in the emission layer (that may correspond to each sub-pixel) has to be formed by a separate process. However, there is a high probability that the emission layer may not be uniformly formed when such multiple forming processes are performed. In contrast, according to exemplary embodiments, a method of manufacturing a high-quality organic light-emitting display apparatus may be implemented.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

1. (canceled)

2. A method of manufacturing an organic light-emitting display apparatus, the method comprising:
preparing a substrate with a plurality of pixel electrodes;
preparing a donor mask, such that the donor mask includes a base substrate, a light-thermal conversion layer on the base substrate, and a reflective layer between the base substrate and the light-thermal conversion layer and having through-holes;
depositing a transfer layer on the light-thermal conversion layer of the donor mask;
aligning the substrate and the donor mask;
preheating at least a portion of the donor mask or the transfer layer; and
irradiating a light source toward the preheated portion of the donor mask or the transfer layer, such that a portion of the transfer layer is transferred from the donor mask to the plurality of pixel electrodes of the substrate, the transferred portion of the transfer layer corresponding to the through-holes in the reflective layer,
wherein:
preheating includes irradiating a preliminary laser beam toward at least a portion of the donor mask, such that a corresponding portion of the transfer layer is preheated; and
irradiating includes irradiating a laser beam different from the preliminary laser beam toward the preheated portions of the donor mask and the transfer layer.

3. The method as claimed in claim 2, wherein the preliminary laser beam is emitted by a preliminary laser beam source, and the laser beam is emitted by a laser beam source different from the preliminary laser beam source.

4. The method as claimed in claim 2, wherein the preliminary laser beam and the laser beam are emitted by a single laser beam.

5. The method as claimed in claim 4, wherein the preliminary laser beam and the laser beam are diverged from the single laser beam by an optical element.

6. The method as claimed in claim 4, wherein the single laser beam emits the preliminary laser beam and the laser beam with a time difference therebetween.

7. The method as claimed in claim 2, wherein an intensity of the preliminary laser beam is lower than an intensity of the laser beam.

8. A method of manufacturing an organic light-emitting display apparatus, the method comprising:
preparing a substrate with a plurality of pixel electrodes;
preparing a donor mask, such that the donor mask includes a base substrate, a light-thermal conversion layer on the base substrate, and a reflective layer between the base substrate and the light-thermal conversion layer and having through-holes;
depositing a transfer layer on the light-thermal conversion layer of the donor mask;
aligning the substrate and the donor mask;
preheating at least a portion of the donor mask or the transfer layer; and
irradiating a light source toward the preheated portion of the donor mask or the transfer layer, such that a portion of the transfer layer is transferred from the donor mask to the plurality of pixel electrodes of the substrate, the transferred portion of the transfer layer corresponding to the through-holes in the reflective layer,
wherein:
preheating includes irradiating a preliminary lamp light toward at least a portion of the donor mask, such that a corresponding portion of the transfer layer is preheated; and
irradiating includes irradiating a lamp light different from the preliminary lamp light toward the preheated portions of the donor mask and the transfer layer,
wherein an intensity of the preliminary lamp light is lower than an intensity of the lamp light.

9. The method as claimed in claim 8, wherein the preliminary lamp light is emitted by a preliminary lamp, and the lamp light is emitted by a lamp different from the preliminary lamp light.

10. The method as claimed in claim 8, wherein the preliminary lamp light and the lamp light are emitted by a single lamp light.

11. The method as claimed in claim 10, wherein the single lamp light emits the preliminary lamp light and the lamp light with a time difference therebetween.

12. (canceled)

13. The method as claimed in claim 5, wherein an intensity of the preliminary laser beam is lower than an intensity of the laser beam.

14. The method as claimed in claim 5, wherein the preliminary laser beam and the laser beam are sequentially irradiated onto a same predetermined area of the donor mask such that the laser beam irradiates an area previously irradiated by the preliminary laser beam.

15. The method as claimed in claim 10, wherein the preliminary lamp light and the lamp light are sequentially irradiated onto a same predetermined area of the donor mask such that the lamp light irradiates an area previously irradiated by the preliminary lamp light.
